(19) United States
(12) Patent Application Publication
(10) Pub. No.: US 2022/0098718 A1
(43) Pub. Date: Mar. 31, 2022

(54) MASK AND EVAPORATION SYSTEM

(71) Applicant: KunShan Go-Visionox Opto-Electronics Co., Ltd, Kunshan (CN)

(72) Inventors: Bing HAN, Kunshan (CN); Zhiyuan ZHANG, Kunshan (CN); Weili LI, Kunshan (CN); Mingxing LIU, Kunshan (CN)

(73) Assignee: KunShan Go-Visionox Opto-Electronics Co., Ltd, Kunshan (CN)

(21) Appl. No.: 17/546,371

(22) Filed: Dec. 9, 2021

Related U.S. Application Data
(63) Continuation of application No. PCT/CN2020/109845, filed on Aug. 18, 2020.

(30) Foreign Application Priority Data
Nov. 21, 2019 (CN) 201911151364.9

(51) Int. Cl. C23C 14/04; C23C 14/24

(52) U.S. Cl. CPC C23C 14/042; C23C 14/24

(57) ABSTRACT

A mask and an evaporation system. The mask includes: at least one mask strip. The at least one mask strip is formed with at least one effective evaporation region and a transition region disposed around the effective evaporation region; the at least one mask strip includes at least two stacked mask bodies; at least part of the at least two mask bodies define a plurality of through holes corresponding to the transition region; the plurality of through holes on at least adjacent two of the at least two mask bodies are arranged in a staggered manner, to prevent evaporation material passing through the plurality of through holes corresponding to the transition region.

### CROSS REFERENCE

The present application is a continuation-application of International (PCT) Patent Application No. PCT/CN2020/109845, filed on Aug. 18, 2020, which claims priority of Chinese Patent Application No. 201911151364.9, filed on Nov. 21, 2019, the entire contents of which are hereby incorporated by reference in its entirety.

### TECHNICAL FIELD

The present disclosure relates to the field of display technologies, and in particular to a mask and an evaporation system.

### BACKGROUND

Currently, during a preparing process of a display panel, it is generally necessary to evaporate a material to a predetermined position of a substrate which is to be evaporated with a mask. However, there is a problem that the mask for evaporation is not closely attached to a surface of the substrate to be evaporated.

### SUMMARY

The main technical problem solved by the present disclosure is to provide a mask and an evaporation system, which can shield the through holes of the mask corresponding to the transition region.

A technical solution adopted by the present disclosure is to provide a mask, including: at least one mask strip, wherein the at least one mask strip is formed with at least one effective evaporation region and a transition region disposed around the effective evaporation region; the at least one mask strip includes at least two stacked mask bodies; at least part of the at least two mask bodies define a plurality of through holes corresponding to the transition region; the plurality of through holes on at least adjacent two of the at least two mask bodies are arranged in a staggered manner, to prevent evaporation material passing through the plurality of through holes corresponding to the transition region.

Another solution adopted by the present disclosure is to provide an evaporation system, including: the mask according to the embodiment as described above and an evaporation apparatus; wherein the evaporation apparatus is configured to evaporate a material to a substrate to be evaporated with the mask.

The beneficial effect of the present disclosure is that the at least one mask strip is formed with at least one effective evaporation region and a transition region disposed around the effective evaporation region; the at least one mask strip includes at least two stacked mask bodies; at least part of the at least two mask bodies define a plurality of through holes corresponding to the transition region; the plurality of through holes on at least adjacent two of the at least two mask bodies are arranged in a staggered manner, to prevent evaporation material passing through the plurality of through holes corresponding to the transition region. That is, the mask bodies in the present disclosure are arranged in different layers, and the mask bodies disposed in different layers are sheltered from each other, to prevent evaporation material passing through the plurality of through holes corresponding to the transition region, such that there is no evaporation material in the position of the substrate to be evaporated corresponding to the transition region of the mask strip during evaporation, which is conducive to reducing a width of the frame of the display panel and improving a usability of the frame of the display panel.

### BRIEF DESCRIPTION OF THE DRAWINGS

In order to more clearly explain the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained according to the structures shown in these drawings.

FIG. 1 is a structural schematic view of a mask according to an embodiment of the present disclosure.

FIG. 2 is a schematic cross-sectional view of a mask strip shown in FIG. 1 along an A-A section line according to an embodiment of the present disclosure.

FIG. 3 is a schematic cross-sectional view of a mask strip shown in FIG. 1 along an A-A section line according to another embodiment of the present disclosure.

FIG. 4 is a schematic cross-sectional view of a mask strip shown in FIG. 1 along an A-A section line according to yet another embodiment of the present disclosure.

FIG. 5 is a structural schematic view of an evaporation system according to an embodiment of the present disclosure.

FIG. 6 is a flowchart of a preparation method for mask according to an embodiment of the present disclosure.

### DETAILED DESCRIPTION

The technical solutions in the embodiments of the present disclosure will be clearly and completely described below in conjunction with the drawings in the embodiments of the present disclosure. Obviously, the described embodiments are only a part of the embodiments of the present disclosure, rather than all the embodiments. Based on the embodiments in the present disclosure, all other embodiments obtained by those skilled in the art without creative work shall fall within the scope of the present disclosure.

A mask strip of a mask is generally formed with an effective evaporation region and a transition region around the effective evaporation region. The effective evaporation region corresponds to an actual display region of a display panel, and the mask strip defines a plurality of openings in the effective evaporation region. To ensure the stability of the preparation process for the mask, the mask strip also defines a plurality of through holes in the transition region. However, during the evaporation process, the position of a substrate to be evaporated corresponding to the through holes in the transition region will also be evaporated with a material to be evaporated, thereby occupying a part of a space for the frame of the display panel, such that the demand for a narrow frame of the display panel may not be achieved.

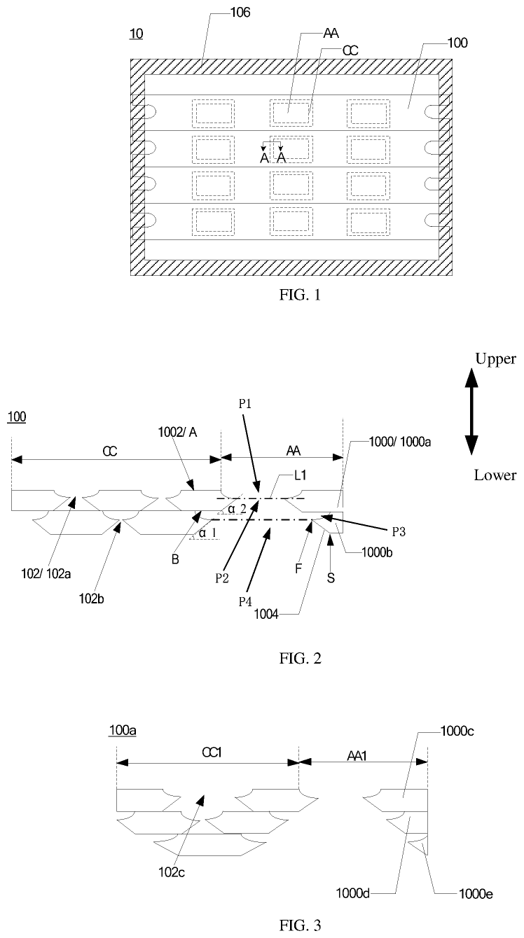

Referring to FIG. 1 to FIG. 2, FIG. 1 is a structural schematic view of a mask according to an embodiment of the present disclosure, and FIG. 2 is a schematic cross-sectional view of a mask strip shown in FIG. 1 along an A-A section line according to an embodiment of the present disclosure. The mask 10 includes a plurality of mask strips 100. Each mask strip 100 is formed with at least one set of effective evaporation regions AA and at least one set of transition regions CC respectively disposed around the at least one set of effective evaporation regions AA. The size and configuration of the effective evaporation region AA may be determined by the design of the display panel to be formed. The size of the effective evaporation region AA may be the same as an actual display region of the display panel. Each of the plurality of mask strips 100 is formed by at least two stacked mask bodies 1000, at least part of the at least two mask bodies 1000 define a plurality of through holes 102 corresponding to the transition region CC, in a stacked direction of the at least two mask bodies 1000, the plurality of through holes 102 on at least adjacent two of the at least two mask bodies 1000 are arranged in a staggered manner, to prevent evaporation material passing through the plurality of through holes 102 corresponding to the transition region CC. That is, a plurality of mask bodies 1000 in the present disclosure are stacked together and arranged in different layers, and the plurality of mask bodies 1000 disposed in different layers are sheltered from each other, such that there is no evaporation material in the position of the substrate to be evaporated corresponding to the transition region of the mask strip during evaporation, which is conducive to reducing a width of the frame of the display panel and improving a usability of the frame of the display panel.

In some embodiments, the at least two mask bodies 1000 may include a first mask body 1000a and a second mask body 1000b which are stacked. The plurality of through holes includes at least one first through hole and at least second through hole. To ensure the process stability of the first mask body 1000a and the second mask body 1000b during the manufacturing process, the first mask body 1000a defines the at least one first through hole 102a at a position corresponding to the transition region CC, and the second mask body 1000b defines the at least one second through hole 102b at a position corresponding to the transition region CC. In a direction from the first mask body 1000a to the second mask body 1000b, the at least one first through hole 102a is blocked by the second mask body 1000b, and the at least one second through hole 102b is blocked by the first mask body 1000a. The mask strip 100 described above has a simple structure, the position of the at least one first through hole 102a and the position of the at least one second through hole 102b in the transition region CC are different, and the size of the at least one first through hole 102a and the size of the at least one second through hole 102b in the transition region CC may also be different. The at least one first through hole 102a and the at least one second through hole 102a in the transition region CC are arranged in a staggered manner, such that the mask strip 100 has no through hole in the transition region CC.

Of course, in other embodiments, the way to realize that the mask strip 100 has no through hole in the transition region CC may also be others. For example, as shown in FIG. 3, FIG. 3 is a schematic cross-sectional view of a mask strip shown in FIG. 1 along an A-A section line according to another embodiment of the present disclosure. The mask strip 100a may include a first mask body 1000c, a second mask body 1000d and a third mask body 1000e which are stacked. When the size of a through hole on one of the mask bodies in the transition region CC1 is relatively large, for example, the size of the first through hole 102c on the first mask body 1000c is relatively large, it is difficult to cover it completely by the second mask body 1000d only. Therefore, the third mask body 1000e may be arranged to cover the first through hole 102c together with the second mask body 1000d. Of course, in other embodiments, more mask bodies in different layers may be arranged, and the number of the mask bodies in different layers in the present disclosure is not limited, as long as the mask bodies in different layers can cooperate with each other such that the mask strip 100a has no through hole in the transition region CC1.

In yet another embodiment, referring to FIG. 2 again, each of the mask bodies 1000 includes an upper surface A and a lower surface B which are opposed to each other. The upper surface A defines a first opening (P1, for example, the arc-shaped opening defined in the mask body 1000a as shown in FIG. 2), and the lower surface B defines a second opening (P2, for example, the opening having an inclined inner wall and defined in the mask body 1000a as showned in FIG. 2) at a position corresponding to the first opening P1. The first opening P1 communicates with the second opening P2. Along a direction away from a first imaginary plane between the first opening and the second opening, the area of a cross section of the second opening P2 in a direction parallel to the first imaginary plane L1 gradually increases, the increasing manner may be linear or non-linear, which is not limited herein. Similarly, along the direction away from the first imaginary plane L1, the area of a cross section of the first opening P1 in the direction parallel to the first imaginary plane L1 may also gradually increase. The above configuration of the first opening P1 and the second opening P2 on the mask body 1000 may reduce the amount of evaporation material attached to inner walls of the first opening P1 and the second opening P2, thereby reducing the waste of evaporation material and the evaporation shadow. Of course, in other embodiments, each of the mask bodies 1000 may include more openings which are communicated with each other. In this case, an opening furthest from a side of the substrate to be evaporated (for example, the second opening P2) may be selected to be configured as above or below.

Further, referring to FIG. 2, the second opening P2 of the mask body 1000a is adjacent to and faces a first opening P3 of the adjacent mask body 1000b, and a maximum cross-sectional area of the second opening P2 of the mask body 1000a in the direction parallel to the first imaginary plane L1 is less than or equal to a minimum cross-sectional area of the first opening P3 of the adjacent mask body 1000b in the direction parallel to the first imaginary plane L1. An orthographic projection of the second opening P2 of the mask body 1000a in the first imaginary plane L1 is located in the middle of an orthographic projection of the first opening P3 of the adjacent mask body 1000b in the first imaginary plane L1. The above configuration of the first opening and the second opening on the adjacent mask bodies 1000 may reduce the amount of vapor deposition material adhering to the inner walls of the first opening and the second opening, thereby reducing vapor deposition material waste and vapor deposition shadow.

For ease of understanding, the above structure will be further described below with the cross-sectional view of FIG. 2 as an example in a perspective of angle. The inner wall of the second opening (P2, P4) of each mask body 1000 may be arranged to be symmetry about an axis, a line between a start position S and an end position F of the inner wall of the second opening P4 at one side of the axis (that is, a shortest line between a point between the first opening P3 and the second opening P4 and a point between the second opening P4 and the lower surface) is defined as a first line. In a direction from the mask body 1000a to the opposite mask body 1000b, the mask strip 100 includes a first surface 1002, and the first surface 1002 may be the surface of the mask strip 100 facing the substrate to be evaporated in the following process. The cross-sectional area of the second opening (P2, P4) of each mask body 1000 gradually increases in a direction away from the first surface 1002. In the direction away from the first surface 1002, an angle α1 between the first line of the mask body 1000b far from the first surface 1002 and a horizontal plane is equal to or less than an angle α2 between the first line of the mask body 1000a close to the first surface 1002 and the horizontal plane. That is, an angle between two extending lines of two first lines of the mask body 1000b at two sides of the axis far from the first surface 1002 is greater than or equal to an angle between two extending lines of two first lines of the mask body 1000a at two sides of the axis close to the first surface 1002.

In the embodiments, for the at least two mask bodies 1000, the angles between the first line and the horizontal plane are same, and the first lines of the at least two mask bodies 1000 extend along a same straight line. The above configuration may make the angle of the second opening (P2, P4) of the mask strip 100 better match an evaporation angle. For example, in the embodiments, for all the mask bodies 1000, the angles between the first line and the horizontal plane are same, the first lines of all the mask bodies 1000 extend along a same straight line, and the angle between the first line and the horizontal plane is the same as the evaporation angle. The evaporation angle is an included angle formed by the evaporation material and the horizontal plane when the evaporation material enters the second opening (P2, P4) of the mask strip 100. In this way, when the evaporation material enters the second opening (P2, P4), less evaporation material remains on the inner wall of the second opening (P2, P4), thereby reducing the waste of the evaporation material and reducing the evaporation shadow.

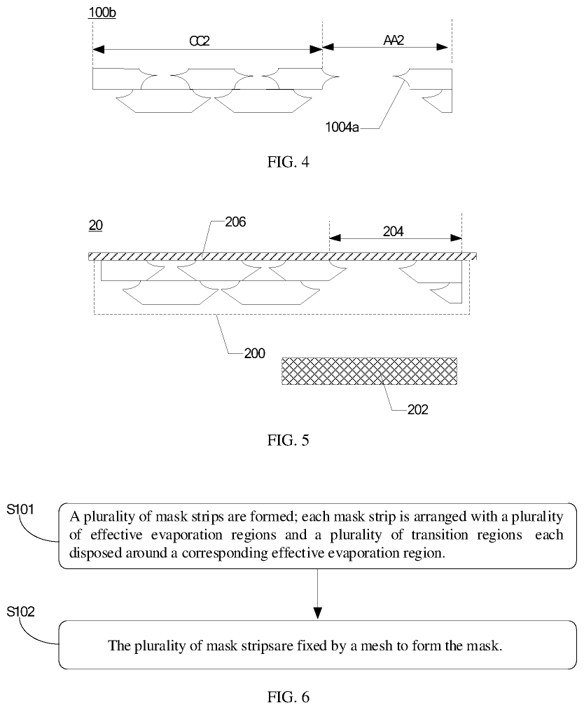

In addition, as shown in FIG. 2, the inner walls 1004 of the second opening P4 at two sides of the axis may be inclined surfaces. The above configuration of the second opening (P2, P4) is relatively simple and easy to implement in terms of technology. Of course, in other embodiments, referring to FIG. 4, FIG. 4 is a schematic cross-sectional view of a mask strip shown in FIG. 1 along an A-A section line according to yet another embodiment of the present disclosure. The inner walls 1004a of the second opening at two sides of the axis may also be arc-shaped surfaces, which is not limited in the present disclosure.

Referring to FIG. 1 again, the mask 10 may further include a frame 106. Two ends of each of the mask bodies 1000 are fixed to the frame 106. The mask bodies 1000 can be independently and not connected with each other; or, overlapping areas of adjacent mask bodies 1000 are connected with each other, and two ends of one mask body 1000 are fixed to the frame 106. The above configuration may better fix the mask strip 100 to the frame and facilitate the use of the mask strip in the vapor deposition process.

Referring to FIG. 5, FIG. 5 is a structural schematic view of an evaporation system according to an embodiment of the present disclosure. The evaporation system 20 includes: the mask 200 in any of the above embodiments and an evaporation apparatus 202. The evaporation apparatus 202 is configured to evaporate material to a substrate 206 to be evaporated with the mask 200. The mask 200 may be disposed below the substrate 206 to be evaporated, and the evaporation apparatus 202 is configured to evaporate material to the surface of the substrate 206 to be evaporated from a side of the mask 200 away from the substrate 206 to be evaporated.

Of course, in other embodiments, in cases that the material of the mask strip of the mask 200 is a magnetic material (for example, metal, etc.), the evaporation system 20 may also include a magnetic apparatus (not shown). The magnetic apparatus and the mask 200 may be located on two opposite sides of the substrate 206 to be evaporated. The magnetic apparatus may be configured to adsorb the mask strips, such that the mask strips are closely attached to the surface of the substrate 206 to be evaporated, and the evaporation shadow is reduced.

Referring to FIG. 1, FIG. 2 and FIG. 6, FIG. 6 is a flowchart of a preparation method for mask according to an embodiment of the present disclosure. The preparation method may be applied to prepare the mask in any of the foregoing embodiments, and the preparation method includes steps as below.

S101: A plurality of mask strips 100 are formed; each mask strip 100 is formed with a plurality of effective evaporation regions AA and a plurality of transition regions CC respectively disposed around a corresponding effective evaporation region AA. In this embodiment, the mask strip 100 is formed by at least two stacked mask bodies 1000. The at least two mask bodies 1000 define a plurality of through holes 102 corresponding to the transition region CC.

S102: The plurality of mask strips 100 are fixed to a frame 106, and the mask 10 is formed; in a stacked direction of the at least two mask bodies 1000, the through holes 102 on adjacent two of at least two mask bodies 1000 are arranged in a staggered manner, such that evaporation material cannot pass through the plurality of through holes corresponding to the transition region CC.

In some embodiments, the plurality of mask strips 100 formed in S101 includes: forming at least two mask bodies 1000 by etching with an etching solution; each of the at least two mask bodies 1000 defines a plurality of openings corresponding to the plurality of effective evaporation regions AA and a plurality of through holes 102 corresponding to the plurality of transition regions CC.

Specifically, the at least two mask bodies 1000 formed by etching with the etching solution may include: providing a mask base, wherein the mask base includes an upper surface and a lower surface which are opposite to each other; forming a plurality of first openings (P1, P3) by etching the upper surface of the mask base; and forming a plurality of second openings (P2, P4) by etching the lower surface of the mask base respectively corresponding to the plurality of first openings (P1, P3), the first opening (P1, P3) and the second opening (P2, P4) are communicated to form the through hole. Alternatively, the at least two mask bodies 1000 formed by etching with the etching solution may include: providing a mask base, wherein the mask base includes an upper surface and a lower surface which are opposite to each other; and forming a plurality of openings penetrating the upper surface and the lower surface by etching the mask base one time.

The plurality of mask strips 100 fixed to the frame 106 in S102 includes: fixing at least two mask bodies 1000 to the frame 106 respectively, wherein overlapping regions between adjacent mask bodies 1000 are in contact with each other. The above method of preparing and forming the mask strip 100 is relatively simple, and the process is easy to implement.

In other embodiments, the plurality of mask strips 100 formed in S101 includes: providing a first core film, and forming a first mask body 1000a on a surface of the first core film by electroplating, wherein the shape of the first core film is the same as the shape of through holes or a first through hole 102a to be formed on the first mask body 1000a, the position of the first core film is the same as the position of the through holes or the first through hole 102a to be formed on the first mask body 1000a, the shape of the through hole is the same as the shape of the through hole formed by the first opening (P1, P3) and the second opening (P2, P4) which are communicated to each other mentioned above; removing the first core film; providing a second core film on a surface of the first mask body 1000a, and forming a second mask body 1000b on the surface of the first mask body 1000a by electroplating, wherein the shape of the second core film is the same as the shape of through holes or a second through hole 102b to be formed on the second mask body 1000b, and the position of the second core film is the same as the position of the through holes or the second through hole 102b to be formed on the second mask body 1000b; and removing the second core film, wherein the first mask body 1000a and the second mask body 1000b are connected to each other.

The plurality of mask strips 100 fixed to the frame 106 in S102 includes: fixing the first mask body 1000a or the second mask body 1000b to the frame 106, wherein overlapping regions between adjacent mask bodies are directly connected together. The above method of preparing and forming the mask strip 100 is relatively simple and easy to implement.

The above are only implementations of the present disclosure, and do not limit the scope of the present disclosure. Any equivalent structure or equivalent process transformation made using the content of the description and drawings of the present disclosure, or direct or indirect application in other related technical fields, is included in the scope of the disclosure.

What is claimed is:

1. A mask, comprising:
at least one mask strip, wherein the at least one mask strip is formed with at least one effective evaporation region and a transition region disposed around the effective evaporation region;
wherein the at least one mask strip comprises at least two stacked mask bodies;
at least part of the at least two mask bodies define a plurality of through holes corresponding to the transition region;
the plurality of through holes on at least adjacent two of the at least two mask bodies are arranged in a staggered manner, to prevent evaporation material passing through the plurality of through holes corresponding to the transition region.

2. The mask according to claim 1, wherein the at least two mask bodies comprise a first mask body and a second mask body which are stacked;
the plurality of through holes comprises at least one first through hole and at least one second through hole;
the first mask body defines the at least one first through hole at a position corresponding to the transition region;
the second mask body defines the at least one second through hole at a position corresponding to the transition region;
in a direction from the first mask body to the second mask body, the at least one first through hole is blocked by the second mask body, and the at least one second through hole is blocked by the first mask body.

3. The mask according to claim 1, wherein each of the at least two mask bodies comprises an upper surface and a lower surface which are opposed to each other;
the upper surface defines a first opening, and the lower surface defines a second opening at a position corresponding to the first opening;
the first opening communicates with the second opening;
along a direction away from a first imaginary plane between the first opening and the second opening, a cross-sectional area of the second opening in a direction parallel to the first imaginary plane gradually increases.

4. The mask according to claim 3, wherein along the direction away from the first imaginary plane, a cross-sectional area of the first opening in the direction parallel to the first imaginary plane gradually increases.

5. The mask according to claim 3, wherein an orthographic projection of the second opening of one of the at least two mask bodies on the first imaginary plane is located in a middle of an orthographic projection of the first opening of an adjacent one of the at least two mask bodies on the first imaginary plane.

6. The mask according to claim 3, wherein the second opening of one of the at least two mask bodies is adjacent to and faces the first opening of an adjacent one of the at least two mask bodies, and a maximum cross-sectional area of the second opening of the one of the at least two mask bodies in the direction parallel to the first imaginary plane is less than or equal to a minimum cross-sectional area of the first opening of the adjacent one of the at least two mask bodies in the direction parallel to the first imaginary plane.

7. The mask according to claim 3, wherein a shortest line between a point between the first opening and the second opening and a point between the second opening and the lower surface is defined as a first line;
the first lines of at least two of the at least two mask bodies extend along a same straight line.

8. The mask according to claim 7, wherein the first lines of all of the at least two mask bodies extend along a same straight line.

9. The mask according to claim 7, wherein the mask strip comprises a first surface configured to contact with a substrate to be evaporated;
an angle α1 between the first line of one of the at least two mask bodies far away from the first surface and a horizontal plane is equal to or less than an angle α2 between the first line of another of the at least two mask bodies close to the first surface and the horizontal plane.

10. The mask according to claim 7, wherein an inner wall of the second opening is an inclined surface.

11. The mask according to claim 1, further comprising:
a frame; wherein two ends of each of the at least two mask bodies is fixed to the frame.

12. The mask according to claim 1, further comprising:
a frame; wherein overlapping regions of adjacent two of the at least two mask bodies are connected to each other, and two ends of one of the at least two mask bodies are fixed to the frame.

13. The mask according to claim 1, wherein
a material of the plurality of mask strips is a magnetic material.

14. An evaporation system, comprising:
the mask according to claim 1 and an evaporation apparatus; wherein the evaporation apparatus is configured to evaporate a material to a substrate to be evaporated with the mask.

15. The evaporation system according to claim 14, further comprising:
a magnetic apparatus; wherein the magnetic apparatus is configured to absorb at least one mask strip of the mask, and the at least one mask strip comprises a magnetic material.
